(19) United States
(12) Patent Application Publication
(10) Pub. No.: US 2022/0076965 A1
(43) Pub. Date: Mar. 10, 2022

(54) SEMICONDUCTOR DEVICE AND METHOD FOR MANUFACTURING THE SAME

(71) Applicant: Kioxia Corporation, Tokyo (JP)

(72) Inventors: Hiroaki MATSUDA, Yokkaichi Mie (JP); Masayuki KITAMURA, Yokkaichi Mie (JP)

(21) Appl. No.: 17/190,827

(22) Filed: Mar. 3, 2021

(30) Foreign Application Priority Data
Sep. 9, 2020 (JP) 2020-151576

(51) Int. Cl. H01L 21/3215; H01L 27/11582

(52) U.S. Cl. CPC H01L 21/3215; H01L 27/11582

(57) ABSTRACT

A semiconductor device includes a stacked body including a plurality of conductive layers insulated from each other, a semiconductor layer extending into the stacked body, and a charge storage layer located between one of the conductive layers and the semiconductor layer. The conductive layer contains tungsten and an auxiliary material. An amount of the auxiliary material is smaller than an amount of tungsten, and an oxide free energy of the auxiliary material is smaller than an oxide free energy of tungsten.

### CROSS-REFERENCE TO RELATED APPLICATION

This application is based upon and claims the benefit of priority from Japanese Patent Application No. 2020-151576, filed on Sep. 9, 2020, the entire contents of which are incorporated herein by reference.

### FIELD

Embodiments described herein relate generally to a semiconductor device and a method for manufacturing the same.

### BACKGROUND

Known is a semiconductor package using a NAND type flash memory as a semiconductor device. As such a NAND type flash memory, proposed is a three-dimensional memory device in which a plurality of conductive layers are stacked on a substrate.

### DESCRIPTION OF THE DRAWINGS

FIG. 1 is a perspective view illustrating an overall configuration of a semiconductor device according to a first embodiment;

FIG. 2 is a cross-sectional view illustrating the overall configuration of the semiconductor device;

FIG. 3 is a cross-sectional view illustrating a configuration of a memory cell of the semiconductor device;

FIG. 4 is a cross-sectional view illustrating a method for manufacturing the semiconductor device;

FIG. 5 is a cross-sectional view illustrating the method for manufacturing the semiconductor device;

FIG. 6 is a cross-sectional view illustrating the method for manufacturing the semiconductor device;

FIG. 7 is a cross-sectional view illustrating the method for manufacturing the semiconductor device;

FIG. 8 is a cross-sectional view illustrating the method for manufacturing the semiconductor device;

FIG. 9 is a cross-sectional view illustrating the method for manufacturing the semiconductor device;

FIG. 10 is a cross-sectional view illustrating the method for manufacturing the semiconductor device;

FIG. 11 is a cross-sectional view illustrating the method for manufacturing the semiconductor device;

FIG. 12 is a cross-sectional view illustrating the method for manufacturing the semiconductor device;

FIG. 13 is a cross-sectional view illustrating the method for manufacturing the semiconductor device;

FIG. 14A is an analysis result showing a state before performing heating treatment on a sample in which molybdenum and tungsten are stacked in the method for manufacturing the semiconductor device;

FIG. 14B is an analysis result showing a state in which molybdenum is diffused into tungsten by performing the heating treatment in the method for manufacturing the semiconductor device;

FIG. 15 is a cross-sectional view illustrating an overall configuration of a semiconductor device according to a second embodiment;

FIG. 16 is a cross-sectional view illustrating a method for manufacturing the semiconductor device;

FIG. 17 is a cross-sectional view illustrating a side wall shape of a conductive layer of a semiconductor device according to a third embodiment;

FIG. 18 is a cross-sectional view illustrating the side wall shape of the conductive layer of the semiconductor device;

FIG. 19 is a cross-sectional view illustrating a side wall shape of a conductive layer of a semiconductor device according to a modification of the third embodiment; and

FIG. 20 is a cross-sectional view illustrating the side wall shape of the conductive layer of the semiconductor device.

### DETAILED DESCRIPTION

Embodiments according to the present disclosure provide a highly reliable semiconductor device. Alternatively, the embodiments according to the present disclosure provide a highly reliable semiconductor device in which occurrence of a shape abnormality in stacked conductive layers is prevented.

In general, according to one embodiment, a semiconductor device includes a stacked body in which a plurality of conductive layers insulated from each other are stacked and an opening common to the plurality of conductive layers is provided, in which the conductive layer contains tungsten and an auxiliary material having a smaller amount than that of tungsten and having smaller oxide free energy than that of tungsten.

In general, according to one embodiment, a method for manufacturing a semiconductor device that forms a stacked body includes: alternately stacking a first conductive layer containing tungsten and a second conductive layer containing an auxiliary material having smaller oxide free energy than that of tungsten to be in contact with each other; performing heating treatment in a state where the first conductive layer and the second conductive layer are stacked; forming a first opening common to the first conductive layer and the second conductive layer; and removing the second conductive layer via the first opening.

In general, according to one embodiment, a method for manufacturing a semiconductor device that forms a stacked body includes: alternatively stacking a conductive layer formed by simultaneously performing film formation of tungsten and an auxiliary material having smaller oxide free energy than that of tungsten, in which a ratio of the auxiliary material to tungsten is equal to or greater than 0.001% and equal to or less than 5%, and an insulating layer; and forming an opening common to the conductive layer and the insulating layer.

Hereinafter, a semiconductor device according to the embodiment will be specifically described with reference to the drawings. In the following description, an element having almost the same function and configuration will be denoted by the same reference sign or a reference sign to which an alphabet is added after the same reference sign, and duplicate description will be provided only when necessary. Each embodiment illustrated below describes a device and a method for embodying a technical idea of the embodiment. The technical idea of the embodiment does not specify a material, a shape, a structure, and an arrangement of a component as follows. The technical idea of the embodiment may be modified in various ways within the scope of the claims.

In each embodiment of the present disclosure, a direction from a substrate to a memory cell is referred to as upward. Conversely, a direction from the memory cell to the substrate is referred to as downward. As described above, for the convenience of description, the term referred to as “upward” or “downward” will be used for description, and for example, a vertical relationship between the substrate and the memory cell may be opposite to that shown in the drawing. In the following description, for example, the description of the “memory cell” on the substrate merely indicates the vertical relationship between the substrate and the memory cell as described above, and other members may be arranged between the substrate and the memory cell.

In the specification, descriptions such as “α includes A, B or C”, “α includes any one of A, B, and C”, and “a includes one selected from a group formed of A, B and C” do not exclude a case in which α includes a plurality of combinations of A to C unless otherwise specified. The descriptions also do not exclude a case in which α includes other elements.

The respective following embodiments may be combined with each other as long as technical conflict therebetween does not occur.

In the respective following embodiments, a memory cell array will be described as an example of the semiconductor device, and the technique of the present disclosure may be applied to a semiconductor device other than the memory cell array (for example, a CPU, a display, and an interposer).

### First Embodiment

[Configuration of Memory Cell Array]

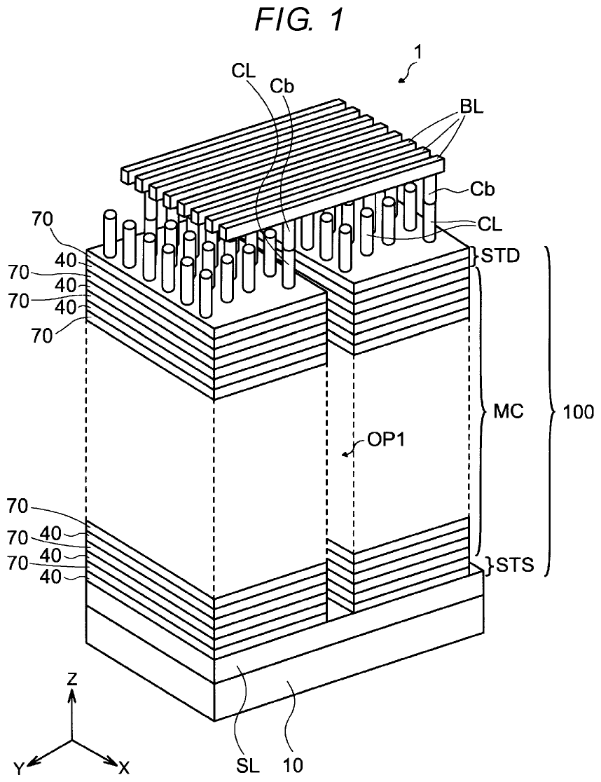

FIG. 1 is a schematic perspective view of a memory cell array 1 of a first embodiment.

In FIG. 1, two directions parallel to a main surface of a substrate 10 and orthogonal to each other are referred to as an X direction and a Y direction. A direction orthogonal to both the X direction and the Y direction is referred to as a Z direction (a stacking direction).

As illustrated in FIG. 1, the memory cell array 1 includes: the substrate 10; a source layer SL provided on the substrate 10; a stacked body 100 provided on the source layer SL; a plurality of columnar portions CL; and a plurality of bit lines BL provided on the stacked body 100.

The substrate 10 is, for example, a silicon substrate. The bit line BL and the source layer SL have conductivity. An insulating layer may be provided between the substrate 10 and the source layer SL.

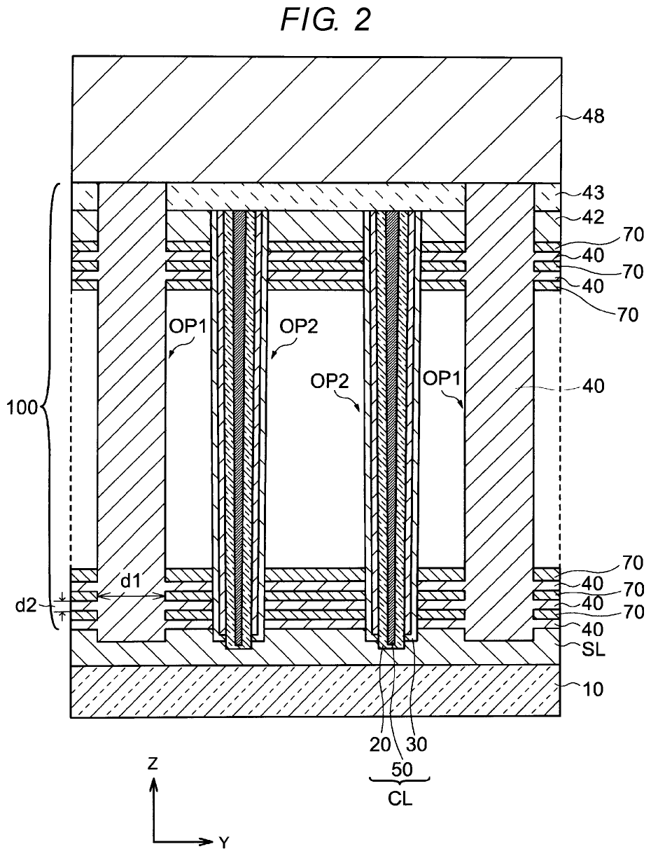

The stacked body 100 is formed with a plurality of conductive layers 70 insulated from each other, and openings OP1 and OP2 common to the plurality of conductive layers 70. The openings OP1 and OP2 extend in the stacking direction (the Z direction) and reach the source layer SL. The opening OP1 extends in the X direction and separates the stacked body 100 into a plurality of blocks in the Y direction. Although details of the opening OP2 will be described later, the columnar portion CL is formed in the opening OP2 (refer to FIG. 2).

The columnar portion CL is formed in a columnar shape or an elliptical columnar shape extending in the stacking direction in the stacked body 100.

The plurality of columnar portions CL are arranged, for example, in a staggered manner. Alternatively, the plurality of columnar portions CL may be arranged in a square grid pattern along the X direction and the Y direction.

The plurality of bit lines BL are separated from each other in the X direction, and each bit line BL extends in the Y direction.

An upper end of a semiconductor layer 20 (refer to FIG. 2), which will be described later, of the columnar portion CL is connected to the bit line BL via a contact portion Cb. The plurality of columnar portions CL selected one by one from the respective blocks separated in the Y direction by the opening OP1 are connected to one common bit line BL.

As illustrated in FIG. 2, an insulating layer 40 is formed in the opening OP1, and insulating layers 42, 43, and 48 are formed on the stacked body 100. However, for the convenience of description, the insulating layers are omitted in FIG. 1.

FIG. 2 is a schematic cross-sectional view of the memory cell array 1. The Y direction and the Z direction illustrated in FIG. 2 correspond to the Y direction and the Z direction illustrated in FIG. 1.

The stacked body 100 includes a plurality of conductive layers 70 stacked on the substrate 10 via the source layer SL. The plurality of conductive layers 70 are periodically stacked in a direction perpendicular to the main surface of the substrate 10 (the stacking direction) via the insulating layer 40. Each conductive layer 70 is a single layer. That is, when a cross-sectional shape of one conductive layer 70 is observed, a single material may be continuous in a film thickness direction of the conductive layer 70 (the Z direction). An interface may not exist inside one conductive layer 70. The film thickness of one conductive layer 70 is, for example, equal to or greater than 5 nm and equal to or less than 100 nm, or equal to or greater than 10 nm and equal to or less than 50 nm.

The insulating layer 40 is formed between the conductive layer 70 and the conductive layer 70 that are adjacent to each other in the stacking direction. The insulating layer 40 is also formed between the source layer SL and the lowermost conductive layer 70. The conductive layers 70 adjacent to each other in the stacking direction may be insulated from each other, and a gap (an air gap) may be formed between the conductive layers 70 adjacent to each other.

The openings OP1 and OP2 are commonly formed in a plurality of conductive layers 70 stacked to each other. The insulating layer 40 is formed in the opening OP1. The insulating layer 40 formed in the opening OP1 is continuous with the insulating layer 40 formed between the conductive layers 70 adjacent to each other in the stacking direction.

The columnar portion CL is formed in the opening OP2. The columnar portion CL includes a memory layer 30, the semiconductor layer 20, and an insulating core layer 50. The core layer 50 is provided in a columnar shape near the center of the opening OP2. The semiconductor layer 20 is provided in a cylindrical shape around a periphery of the core layer 50. The memory layer 30 is provided in a cylindrical shape around a periphery of the semiconductor layer 20. The memory layer 30 is in contact with side walls of the opening OP2 (the conductive layers 70 and the insulating layers 40 that are alternately stacked). In other words, in the above-described configuration, the semiconductor layer 20 penetrates the stacked body 100. The memory layer 30 (including a charge storage layer 32 which will be described later) is provided between the conductive layer 70 and the semiconductor layer 20.

The insulating layer 42 is provided on the conductive layer 70 of the uppermost layer, and the insulating layer 43 is provided on the aforementioned insulating layer 42. The conductive layer 70 of the uppermost layer is in contact with the insulating layer 42.

The conductive layer 70 contains “tungsten” and an “auxiliary material” having a smaller amount than that of tungsten and having smaller oxide free energy than that of tungsten. In other words, the conductive layer 70 contains tungsten as a main component and the auxiliary material as an auxiliary component (an additive or an impurity).

The oxide free energy of tungsten is about −510 [kJ/mol]. Therefore, as the auxiliary material, a material whose oxide free energy is smaller than −510 [kJ/mol] may be used. Specifically, as the auxiliary material, any one of chromium (about −560 [kJ/mol]), manganese (about −625 [kJ/mol]), niobium (about −640 [kJ/mol]), molybdenum (about −650 [kJ/mol]), tantalum (about −670 [kJ/mol]), silicon (about −725 [kJ/mol]), titanium (about −800 [kJ/mol]), aluminum (about −940 [kJ/mol]), magnesium (about −1040 [kJ/mol]), and thorium (about −1046 [kJ/mol]) may be used. A value in parentheses after the above-described element name is the oxide free energy of each element.

Since the oxide free energy of the auxiliary material is smaller than the oxide free energy of tungsten, the auxiliary material contained in the conductive layer 70 is more easily oxidized than tungsten. For example, when an opening common to the plurality of conductive layers 70 is formed in the stacked body 100 as shown in the opening OP1, a side surface of the conductive layer 70 is exposed to the opening OP1 in a manufacturing process. When the conductive layer exposed to the opening OP1 does not contain the auxiliary material, and when heating treatment is performed in the above-described state, there is a possibility that tungsten is oxidized and a shape abnormality referred to as a whisker occurs.

In the embodiment, since the auxiliary material is more easily oxidized than tungsten, even when the heating treatment is performed in the state where the side surface of the conductive layer 70 is exposed to the opening OP1 as described above, the auxiliary material is preferentially oxidized. As a result, oxidation of tungsten can be prevented such that the occurrence of the whisker can be prevented.

As the auxiliary material used for the conductive layer 70, a material whose combination with tungsten is all-proportional solid solution type may be used. As described above, since the combination thereof is all-proportional solid solution type, it is possible to reduce high resistance of the conductive layer 70.

Molybdenum, niobium, tantalum, and chromium may be used as the auxiliary material whose combination with tungsten is all-proportional solid solution type.

Specific resistance of tungsten is about 5.65 [μΩ·cm]. Therefore, as the auxiliary material, a material whose specific resistance is equal to or less than 5.65 [μΩ·cm], or equal to or less than three times of the specific resistance of tungsten (about 17 [μΩ·cm]) may be used. Specifically, as the auxiliary material, anyone of thorium (about 14.7 [μΩ·cm]), niobium (about 12.5 [μΩ·cm]), tantalum (about 12.5 [μΩ·cm]), molybdenum (about 5.2 [μΩ·cm]), and gold (about 2.35 [μΩ·cm]) may be used. A value in parentheses after the element name is the specific resistance of each element. As the auxiliary material, when the specific resistance of the auxiliary material is equal to or less than three times of the specific resistance of tungsten, an operation of the memory cell array 1 is not substantially adversely affected.

A ratio of the auxiliary material to tungsten contained in the conductive layer 70 is equal to or greater than 0.001% and equal to or less than 5%, equal to or greater than 0.003% and equal to or less than 3%, or equal to or greater than 0.005% and equal to or less than 1%. The ratio of the auxiliary material thereto is an average value in the conductive layer 70 of one layer. Specifically, the ratio thereof is an average value of composition analysis performed on the conductive layer 70 of one layer. Secondary ion mass spectrometry (SIMS) may be used as the composition analysis. As another method, energy dispersive X-ray analysis (EDX analysis) may be used. The ratio may be calculated by performing line measurement of the EDX analysis in one of the directions in which the conductive layer 70 spreads (for example, in a horizontal direction in a certain cross-sectional view) with respect to the conductive layer 70 of one layer. Alternatively, the ratio may be calculated by performing mapping measurement of the EDX analysis with respect to the conductive layer 70 of one layer.

The auxiliary material contained in the conductive layer 70 is diffused outward by performing the heating treatment. That is, for example, when the heating treatment is performed in the state where the side surfaces of the conductive layer 70 are exposed to the openings OP1 and OP2 as described above, the auxiliary material is diffused into the conductive layer 70 toward the openings OP1 and OP2. As a result, the auxiliary material is unevenly distributed at opening end portions near the openings OP1 and OP2 of the conductive layer 70. That is, in, concentration of the auxiliary material at the opening end portions near the openings OP1 and OP2 of the conductive layer 70 is higher than concentration of the auxiliary material inside the pattern of the conductive layer 70.

Details of the opening OP2 will be described later, and since the opening OP2 is formed before the opening OP1, the auxiliary material is more unevenly distributed at the opening end portion (a second opening end portion) of the conductive layer 70 near the opening OP2 in comparison with the opening end portion (a first opening end portion) of the conductive layer 70 near the opening OP1. That is, the concentration of the auxiliary material at the second opening end portion is higher than the concentration of the auxiliary material at the first opening end portion.

The ratio of the auxiliary material to tungsten is set within the above-described range, thereby making it possible to achieve a configuration in which the auxiliary material is unevenly distributed at the opening end portion and tungsten with high concentration exists in the rest of regions. As a result, in a region of the conductive layer 70 that functions as wiring, it is possible to prevent the occurrence of a tungsten whisker near the opening end portion while maintaining the original low resistance of tungsten.

As the insulating layer 40, inorganic insulating layers such as silicon oxide (SiO₂), silicon nitride (SiN), aluminum oxide (Al₂O₃), and aluminum nitride (AlN) may be used. A TEOS layer may be used as the insulating layer 40. The TEOS layer is a silicon oxide layer formed by a CVD method using tetra ethyl ortho silicate (TEOS) as a raw material.

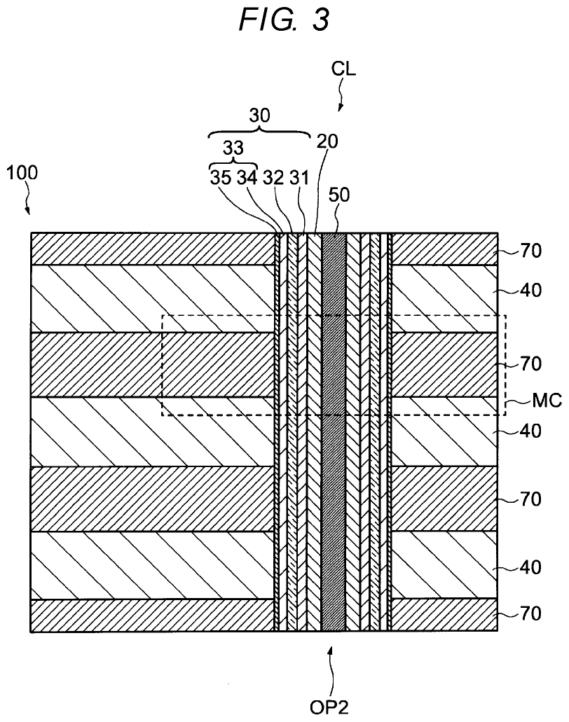

FIG. 3 is a partially enlarged cross-sectional view of FIG. 2.

The columnar portion CL is a structure including the memory layer 30, the semiconductor layer 20, and the insulating core layer 50. The semiconductor layer 20 extends in the stacked body 100 in the cylindrical shape in the stacking direction. The memory layer 30 is provided between the conductive layer 70 and the semiconductor layer 20, and surrounds the semiconductor layer 20 from an outer peripheral side of the semiconductor layer 20. The core layer 50 is provided inside the cylindrical-shaped semiconductor layer 20.

An upper end of the semiconductor layer 20 is connected to the bit line BL via the contact portion Cb illustrated in FIG. 1. As illustrated in FIG. 2, a lower end of the semiconductor layer 20 is connected to the source layer SL.

The memory layer 30 includes a tunnel insulating layer 31, the charge storage layer 32, and a block insulating layer 33. The block insulating layer 33, the charge storage layer 32, the tunnel insulating layer 31, and the semiconductor layer 20 extend continuously in the stacking direction of the stacked body 100. The block insulating layer 33, the charge storage layer 32, and the tunnel insulating layer 31 are provided between the conductive layer 70 and the semiconductor layer 20 in this order from the side of the conductive layer 70. The tunnel insulating layer 31 is in contact with the semiconductor layer 20. The block insulating layer 33 is in contact with the conductive layer 70. The charge storage layer 32 is provided between the block insulating layer 33 and the tunnel insulating layer 31.

The semiconductor layer 20, the memory layer 30, and the conductive layer 70 form the memory cell MC. In FIG. 3, one memory cell MC is schematically represented by a broken line. The memory cell MC has a vertical transistor structure in which the conductive layer 70 surrounds the periphery of the semiconductor layer 20 via the memory layer 30.

In the memory cell MC having the vertical transistor structure, the semiconductor layer 20 functions as a channel and the conductive layer 70 functions as a control gate. The charge storage layer 32 functions as a data storage layer that stores charges injected from the semiconductor layer 20.

As described above, the plurality of memory cells MC are arranged in the stacking direction of the plurality of conductive layers 70, and the plurality of conductive layers 70 are respectively connected to the plurality of memory cells MC. Among the conductive layers 70, the conductive layer 70 near the block insulating layer 33 functions as the control gate. A voltage to the conductive layer 70 connected to the memory cell MC is controlled, thereby controlling writing or erasing in the memory cell MC.

The semiconductor storage device of the embodiment is a non-volatile semiconductor storage device that can electrically and freely write or erase data to the memory cell MC, and that can store a stored content even when power is turned off.

The memory cell MC is, for example, a charge trap type memory cell. The charge storage layer 32 includes a large number of trap sites that capture charges in the insulating layer. The charge storage layer 32 includes, for example, a silicon nitride layer.

The tunnel insulating layer 31 serves as a voltage barrier when the charges are injected from the semiconductor layer 20 into the charge storage layer 32, or when the charges stored in the charge storage layer 32 are diffused in the direction of the semiconductor layer 20. The tunnel insulating layer 31 includes, for example, a silicon oxide layer.

The block insulating layer 33 prevents the charges stored in the charge storage layer 32 from being diffused into the conductive layer 70. The block insulating layer 33 prevents back tunneling of electrons from the conductive layer 70 during an erasing operation.

The block insulating layer 33 includes a first block layer 34 and a second block layer 35. The first block layer 34 is, for example, a silicon oxide layer and is in contact with the charge storage layer 32. The second block layer 35 is provided between the first block layer 34 and the conductive layer 70, and is in contact with the conductive layer 70.

The second block layer 35 is a layer having a dielectric constant higher than that of the silicon oxide layer, and is, for example, a metal oxide layer. For example, the second block layer 35 is an aluminum oxide layer or a hafnium oxide layer.

The memory layer 30 is provided between a side surface of the conductive layer 70 on the side of the columnar portion CL and a side surface of the semiconductor layer 20 opposite to the side surface of the conductive layer 70, and is in contact with the side surfaces thereof. A side surface of the semiconductor layer 20 on the side of the insulating layer 40 is not exposed to the insulating layer 40, and is covered with the memory layer 30 and protected thereby.

Between the side surface of the conductive layer 70 and the side surface of the semiconductor layer 20, the plurality of layers are continuously provided in a direction of connecting the side surfaces thereof. The plurality of conductive layers 70 stacked via the insulating layers 40 are physically combined with the columnar portion CL and supported by the columnar portion CL.

As illustrated in FIG. 1, a drain-side select transistor STD is provided at an upper end portion of the columnar portion CL, and a source-side select transistor STS is provided at a lower end portion thereof. For example, the conductive layer 70 of the lowermost layer functions as a control gate for the source-side select transistor STS. For example, the conductive layer 70 of the uppermost layer functions as a control gate for the drain-side select transistor STD.

As illustrated in FIG. 1, the plurality of memory cells MC are provided between the drain-side select transistor STD and the source-side select transistor STS. The plurality of memory cells MC, the drain-side select transistor STD, and the source-side select transistor STS are connected in series through the semiconductor layer 20, thereby forming one memory string. For example, the memory strings are arranged in the staggered manner in a plane direction parallel to an X-Y plane, and the plurality of memory cells MC are three-dimensionally provided in the X direction, the Y direction, and the Z direction.

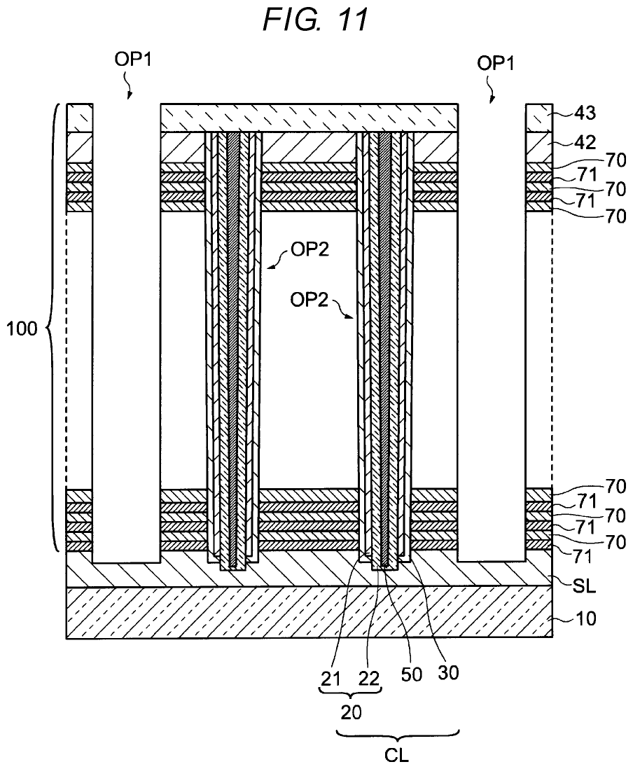

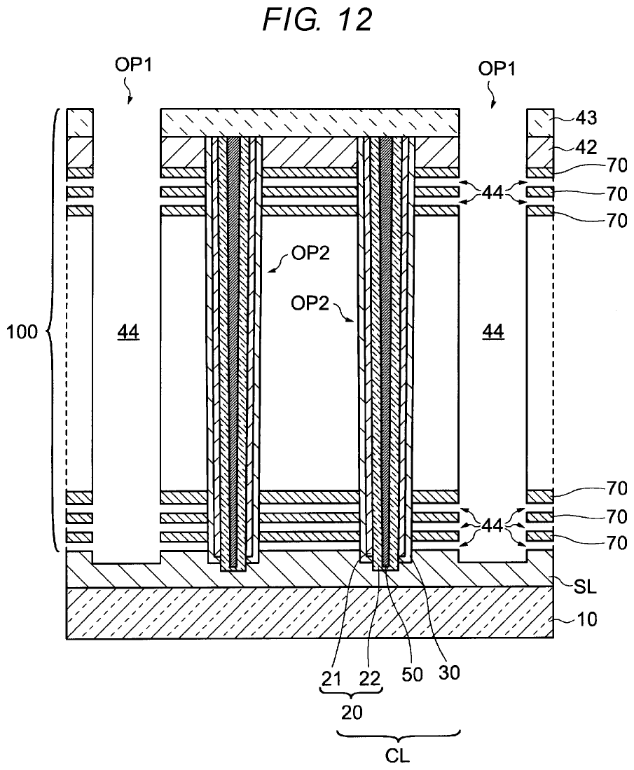

As will be described later, the insulating layer 40 between the conductive layers 70 adjacent to each other in the stacking direction is formed in a region (refer to FIG. 12) where a conductive layer 71 (refer to FIG. 11) formed between the conductive layers 70 is removed by etching through the opening OP1.

After that, as illustrated in FIG. 2, the insulating layer 48 is formed on the insulating layer 43. An upper end of the opening OP1 is covered with the insulating layer 48.

A distance d1 between the conductive layers 70 adjacent to each other in the Y direction via the opening OP1 is greater than a distance d2 between the conductive layers 70 adjacent to each other in the Z direction via the insulating layer 40. The distance d1 between the conductive layers 70 in the Y direction is equivalent to a width of the opening OP1 in the Y direction. The distance d2 between the conductive layers 70 in the Z direction is equivalent to a film thickness of the insulating layer 40.

According to the embodiment, the insulating layer 40 is formed between the control gates (conductive layers 70) of the memory cells MC adjacent to each other in the stacking direction. Therefore, wiring capacitance between the upper and lower conductive layers 70 can be reduced, and the memory cell MC can be operated at a high speed. It is possible to prevent interference between adjacent cells such as threshold fluctuation caused by capacitive coupling between the upper and lower conductive layers 70.

The embodiment provides a configuration in which the conductive layers 70 adjacent to each other in the stacking direction are insulated by the insulating layer 40, and the conductive layer 70 may be insulated by the gap (the air gap). That is, in the embodiment, the insulating layer 40 may be replaced with the gap. Alternatively, the embodiment may provide a structure in which the insulating layer 40 is formed between the conductive layers 70 adjacent to each other in the stacking direction, and the insulating layer 40 is not formed in the opening OP1. Alternatively, the embodiment may provide a structure in which the insulating layer 40 is formed between the conductive layers 70 adjacent to each other in the stacking direction, and the insulating layer 40 of a cylindrical shape is formed in the opening OP1. When the insulating layer 40 of the cylindrical shape is formed in the opening OP1, the conductive layer may be formed in a hollow portion of the cylindrical shape. The conductive layer formed in the hollow portion may be used as wiring.

[Method for Manufacturing Memory Cell Array]

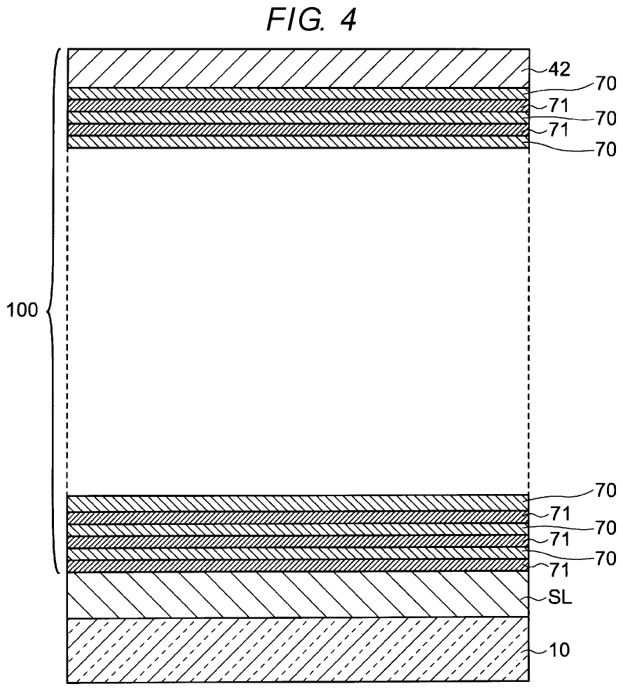

Next, a method for manufacturing the memory cell array 1 of the first embodiment will be described with reference to FIG. 4 to FIG. 13.

As illustrated in FIG. 4, the source layer SL is formed on the substrate 10, and the stacked body 100 is formed on the source layer SL.

The conductive layer 71 is formed on a surface of the source layer SL, and the conductive layer 70 is formed on the conductive layer 71. After that, a step of alternately stacking the conductive layer 71 and the conductive layer 70 one layer by one layer is repeated. The conductive layer 70 and the conductive layer 71, which are alternately stacked, are in contact with each other.

The conductive layer 70 may be referred to as a “first conductive layer”. The conductive layer 71 may be referred to as a “second conductive layer”. The conductive layer 70 (the first conductive layer) is a conductive layer containing tungsten. That is, the conductive layer 70 is a conductive layer containing tungsten as a main component. The conductive layer 71 (the second conductive layer) is a conductive layer containing the auxiliary material. That is, the conductive layer 71 is a conductive layer containing the auxiliary material whose oxide free energy is smaller than that of tungsten. In the embodiment, the conductive layer 71 is a conductive layer containing the auxiliary material as a main component. In the following description of the manufacturing method, an example in which molybdenum is used as the auxiliary material will be described. However, a material other than molybdenum may be used as the auxiliary material.

The insulating layer 42 is formed on the conductive layer 70 of the uppermost layer. The conductive layer 70 of the uppermost layer is formed between the conductive layer 71 of the uppermost layer and the insulating layer 42.

Heating treatment is performed in a state illustrated in FIG. 4. By performing the heating treatment, molybdenum (the auxiliary material) in the conductive layer 71 is diffused into tungsten of the conductive layer 70. A diffusion amount of molybdenum can be controlled by temperature and time of the heating treatment. In the embodiment, the heating treatment is performed so that a ratio of molybdenum to tungsten in the conductive layer 70 after performing the heating treatment is equal to or greater than 0.001% and equal to or less than 5%. Heating treatment conditions are, for example, equal to or higher than 500° C. and equal to or lower than 1000° C., and equal to or longer than 1 minute and equal to or shorter than 1 hour.

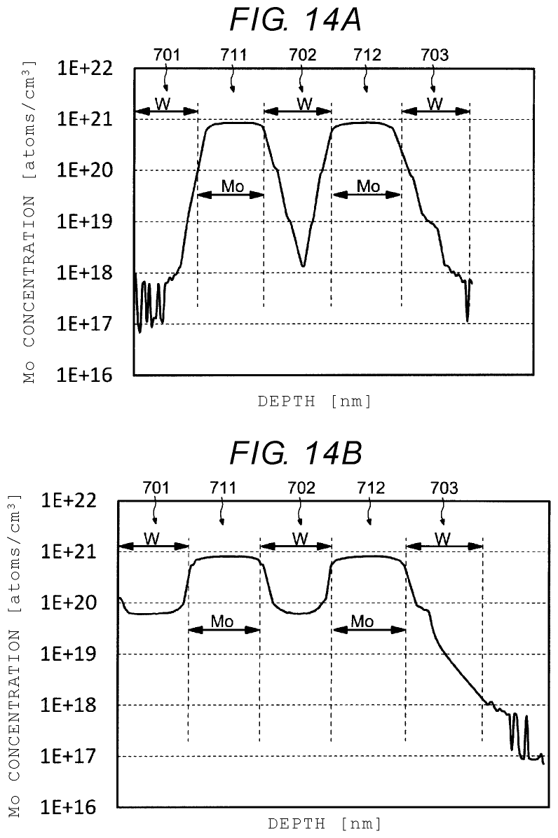

Here, the diffusion of molybdenum into tungsten by the heating treatment will be described with reference to FIG. 14A and FIG. 14B. FIG. 14A is an analysis result showing a state before performing the heating treatment on a sample in which molybdenum and tungsten are stacked in the method for manufacturing the semiconductor device according to the embodiment. FIG. 14B is an analysis result showing a state in which molybdenum is diffused into tungsten by performing the heating treatment in the method for manufacturing the semiconductor device according to the embodiment. A graph of FIG. 14A shows a SIMS analysis result with respect to a sample immediately after tungsten and molybdenum are alternately stacked (before the heating treatment). A graph of FIG. 14B shows a SIMS analysis result after performing the heating treatment at 1000° C. for 5 minutes on a sample in which tungsten and molybdenum are alternately stacked. A horizontal axis of the graphs illustrated in FIG. 14A and FIG. 14B indicates a depth of sputtering the sample during the SIMS analysis, and a vertical axis thereof indicates the concentration of molybdenum.

As can be seen from FIG. 14A and FIG. 14B, the concentration of molybdenum contained in tungsten (W) layers 701, 702, and 703 is different before and after performing the heating treatment. Specifically, the sample after performing the heating treatment contains molybdenum (Mo) of 6×10¹⁹ [atoms/cm³] or more from the tungsten layers 701, 702, and 703 at all points in the film thickness direction. As described above, the heating treatment is performed in the state where tungsten and molybdenum are alternately stacked, thereby making it possible to allow molybdenum to be diffused from molybdenum layers 711 and 712 to the tungsten layers 701, 702 and 703, and to form a tungsten layer containing molybdenum of 0.001% or more and 5% or less. The concentration of molybdenum in the tungsten layer can be adjusted by controlling the temperature and time of the heating treatment.

An amount of the auxiliary material diffused from the conductive layer 71 to the conductive layer 70 is an amount that does not affect the function of the conductive layer 70.

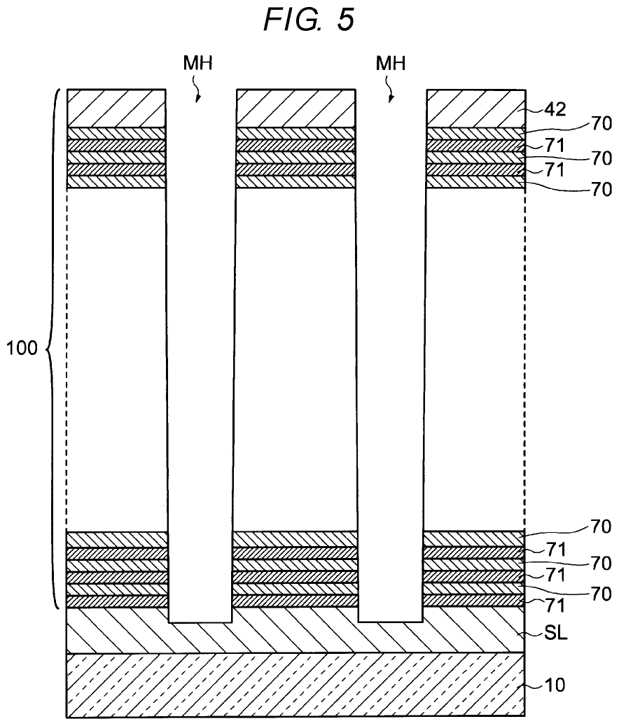

Next, as illustrated in FIG. 5, a plurality of memory holes MH are formed in the stacked body 100 including the plurality of conductive layers 70, the plurality of conductive layers 71, and the insulating layer 42. In the following description, the memory hole MH may be referred to as a “second opening”. In other words, when the above-described configuration is described by using a second opening OP2, the second opening OP2 common to the plurality of conductive layers 70 (the first conductive layer) and the plurality of conductive layers 71 (the second conductive layer) is formed. The memory hole MH is formed by a reactive ion etching (RIE) method using a mask which is not illustrated. The memory hole MH penetrates the stacked body 100 and reaches the source layer SL.

The plurality of conductive layers 70 (tungsten) and the plurality of conductive layers 71 (molybdenum) are etched by, for example, the RIE method using a gas containing chlorine. Accordingly, it is possible to form an appropriately shaped memory hole MH with high throughput.

When the plurality of conductive layers 70 and the plurality of conductive layers 71 are collectively etched as described above, a material having a small difference in an etching rate between the two conductive layers 70 and 71 with respect to the RIE method is used as a material of the conductive layer 70 and the conductive layer 71. In the embodiment, since tungsten is used as the conductive layer 70, for example, a material whose melting point of chloride is close to tungsten may be used as the conductive layer 71. Here, since the melting point of tungsten chloride is about 275° C., as the conductive layer 71, any one of molybdenum (about 194° C.), tantalum (about 216° C.), niobium (about 204.7° C.), and gold (about 254° C.) may be used as an example thereof. A value in parentheses after the element name is the melting point of chloride of each element.

The memory layer 30 is formed in the memory hole MH in a later step. A voltage required for writing or erasing is different depending on the film thickness of the memory layer 30. Therefore, in order to obtain stable characteristics in the plurality of memory cells MC, it is desirable that a side wall of the memory hole MH is close to a linear shape. That is, when the side wall of the memory hole MH is desired to be close to the linear shape, as described above, the material having the small difference in the etching rate between the two conductive layers 70 and 71 with respect to the RIE method used for forming the memory hole MH may be selected as the material for the conductive layer 70 and the conductive layer 71.

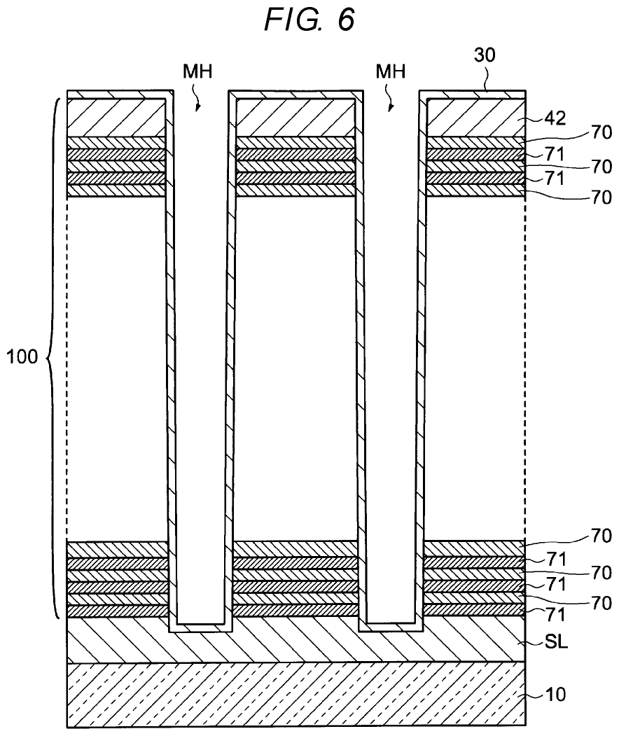

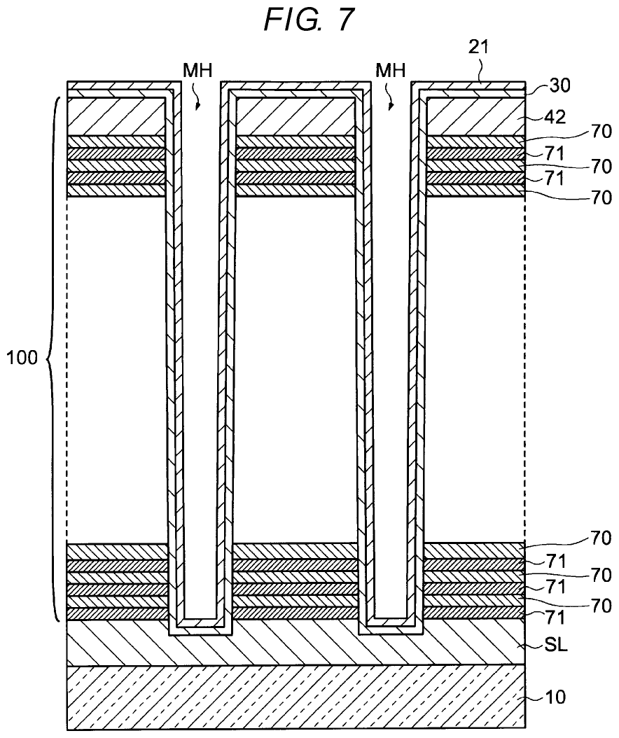

The memory layer 30 is formed on the side surface of the memory hole MH and a bottom thereof as illustrated in FIG. 6, and a cover layer 21 is formed inside the memory layer 30 as illustrated in FIG. 7.

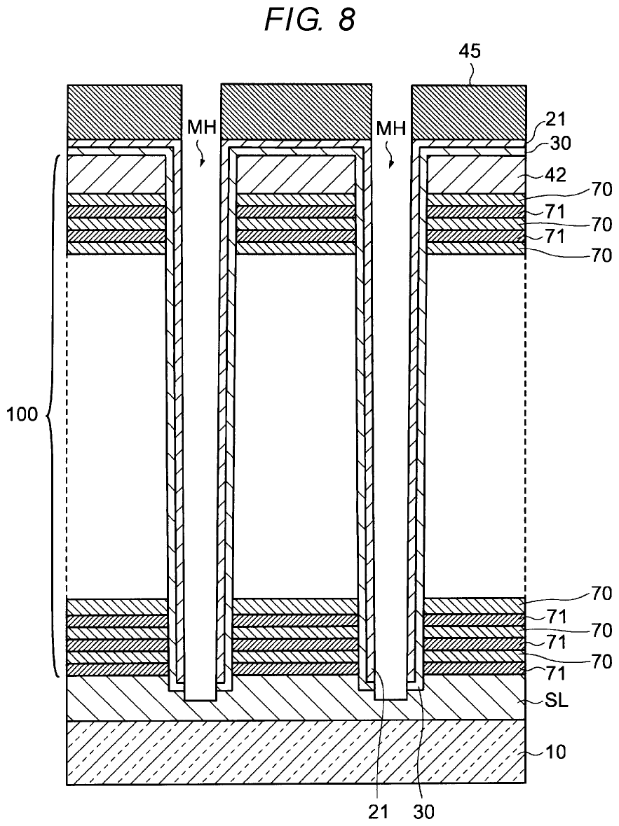

As illustrated in FIG. 8, a mask layer 45 is formed on an upper surface of the stacked body 100, and the cover layer 21 and the memory layer 30 formed on the bottom of the memory hole MH are removed by the RIE method. At the time of performing the RIE method, the memory layer 30 formed on the side surface of the memory hole MH is covered with the cover layer 21 and protected thereby. Therefore, the memory layer 30 formed on the side surface of the memory hole MH is not damaged by the RIE method.

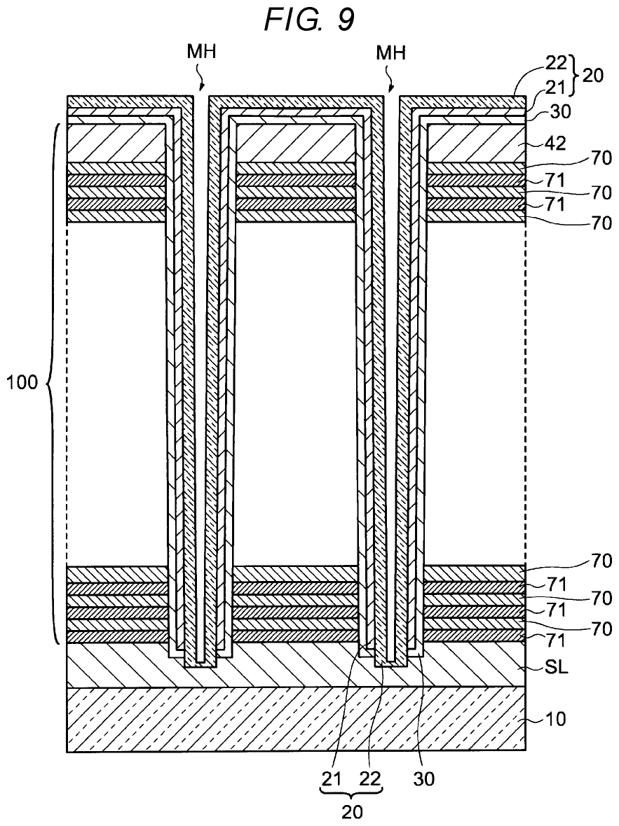

After the mask layer 45 is removed, a semiconductor layer 22 is formed in the memory hole MH as illustrated in FIG. 9. The semiconductor layer 22 is formed on a side surface of the cover layer 21 and the source layer SL exposed at the bottom of the memory hole MH.

The cover layer 21 and the semiconductor layer 22 are formed as, for example, an amorphous silicon layer, and then crystallized into a polycrystalline silicon layer by the heating treatment. The cover layer 21 forms a part of the above-described semiconductor layer 20 together with the semiconductor layer 22. By performing the above-described step, the plurality of memory cells MC arranged in a direction in which the conductive layer 70 and the conductive layer 71 are stacked are formed in the memory hole MH (the second opening).

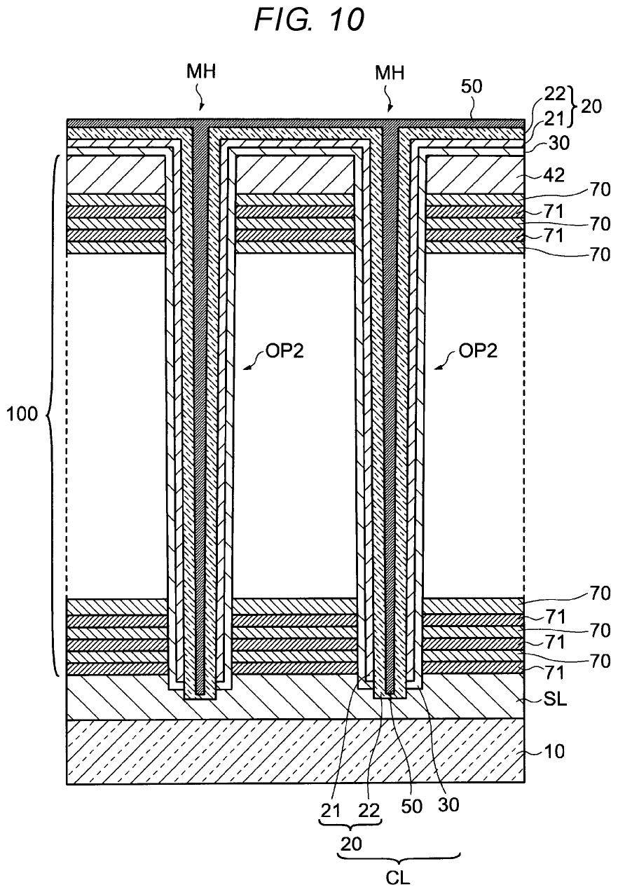

As illustrated in FIG. 10, the core layer 50 is formed inside the semiconductor layer 22. The columnar portion CL is formed by stacking the memory layer 30, the semiconductor layer 20, and the core layer 50.

Each layer deposited on the insulating layer 42 illustrated in FIG. 10 is removed by chemical mechanical polishing (CMP) and etch back. After that, as illustrated in FIG. 11, the insulating layer 43 is formed on the insulating layer 42. The insulating layer 43 covers upper ends of the stacking forming the columnar portion CL.

Next, a plurality of openings OP1 are formed in the stacked body 100 including the insulating layer 43, the insulating layer 42, the plurality of conductive layers 70, and the plurality of conductive layers 71 by the RIE method using the mask which is not illustrated. In the following description, the opening OP1 may be referred to as a “first opening”. In other words, when the above-described configuration is described by using a first opening OP1, the first opening OP1 common to the plurality of conductive layers 70 (the first conductive layer) and the plurality of conductive layers 71 (the second conductive layer) is formed.

As illustrated in FIG. 11, the opening OP1 penetrates the stacked body 100 in the vicinity of the columnar portion CL, and reaches the source layer SL. In the same manner as that of the case of forming the memory hole MH, the plurality of conductive layers 70 (tungsten) and the plurality of conductive layers 71 (molybdenum) are etched by, for example, the RIE method using the gas containing chlorine.

Next, the conductive layer 71 is removed by an etching solution supplied via the opening OP1. By removing the conductive layer 71, as illustrated in FIG. 12, a gap 44 is formed between the conductive layers 70 adjacent to each other in the stacking direction.

As described above, as the etching solution for removing the conductive layer 71, it is possible to use an etching solution whose selection ratio of an etching rate of molybdenum (or another auxiliary material) with respect to tungsten is large. For example, as the etching solution, it is possible to use a phosphoric acid etching solution which contains phosphoric acid as a main component, and to which nitric acid, acetic acid, and water are added. The etching solutions etch molybdenum, but hardly etch an insulating layer such as tungsten and a silicon oxide film. Therefore, the gap 44 based upon the conductive layer 71 can be formed while the shapes of the insulating layer 43, the insulating layer 42, and the plurality of conductive layers 70 are hardly changed.

The second block layer 35 illustrated in FIG. 3 provided on the outermost periphery of the columnar portion CL also has resistance with respect to the etching solution, and the etching of the side surface of the columnar portion CL caused by the etching solution infiltrating through the gap 44 is prevented.

Since an upper end of the columnar portion CL is covered with the insulating layer 43, etching from the upper end side of the columnar portion CL can be prevented.

The plurality of conductive layers 70 stacked via the gaps 44 are supported by the columnar portion CL. A lower end of the columnar portion CL is supported by the source layer SL and the substrate 10, and the upper end thereof is supported by the insulating layers 42 and 43.

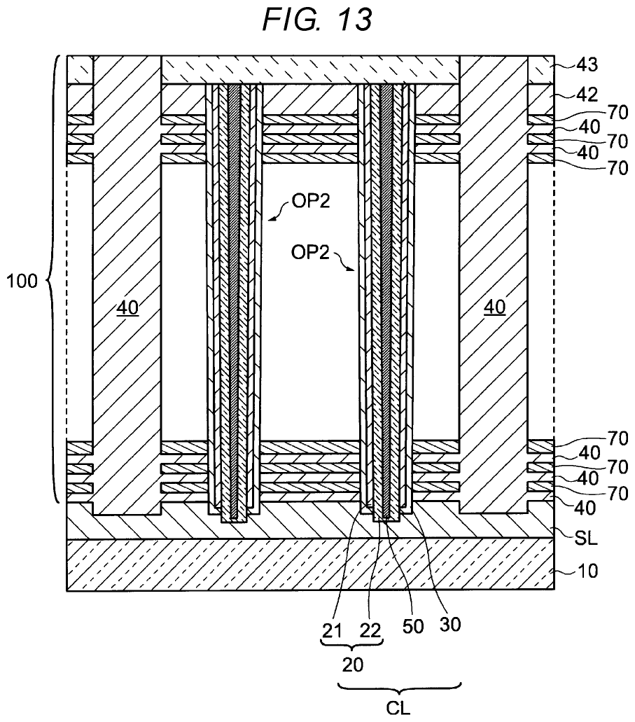

As illustrated in FIG. 13, the insulating layer 40 is formed in the gap 44 formed by removing the conductive layer 71. For example, a silicon oxide film is formed as the insulating layer 40 by a chemical vapor deposition (CVD) method using TEOS as raw material gas. The raw material gas infiltrates into the gap 44 via the opening OP1, and the insulating layer 40 is deposited in the gap 44.

By the above-described step, as illustrated in FIG. 13, the insulating layer 40 is formed between the conductive layers 70 adjacent to each other in the stacking direction. That is, the step forms the memory sell array 1 including the stacked body 100 including the plurality of conductive layers 70 alternately stacked and the plurality of insulating layers 40; the columnar portion CL provided in the opening OP2 penetrating the stacked body 100; and the insulating layer 40 provided in the opening OP1 penetrating the stacked body 100.

As described above, for example, in the steps illustrated in FIG. 5, FIG. 11, and FIG. 12, tungsten is exposed on the side surface of the conductive layer 70. In a related-art structure, when the heating treatment is performed in such state, tungsten may be oxidized and a whisker may occur.

However, in the embodiment, molybdenum is diffused into tungsten of the conductive layer 70 as illustrated in FIG. 14A and FIG. 14B by the heating treatment performed in the state illustrated in FIG. 4. Molybdenum in the conductive layer 70 is diffused outward by performing the heating treatment and is unevenly distributed at the opening end portion of the conductive layer 70. Molybdenum is more easily oxidized than tungsten. Therefore, when the heating treatment is performed in the state illustrated in FIG. 5, FIG. 11, and FIG. 12, molybdenum unevenly distributed at the end portion of the conductive layer 70 is preferentially oxidized, such that the oxidation of tungsten is prevented and the occurrence of the whisker is prevented.

In particular, when the conductive layers 70 adjacent to each other in the stacking direction are exposed together in the opening OP1 common to the plurality of conductive layers 70 as shown in the embodiment, a distance between the exposed conductive layers 70 is significantly close. Here, even though a slight whisker, which is not a problem in a normal semiconductor device, occurs, a problem such as a short circuit between the conductive layers occurs. However, in the configuration according to the embodiment, since the occurrence of the whisker is prevented, the occurrence of the above-described problem can be prevented.

As described above, according to the memory cell array 1 according to the embodiment, since the occurrence of a shape abnormality such as the whisker in the conductive layer 70 is prevented, the memory cell array 1 having high reliability can be achieved.

### Second Embodiment

[Configuration of Memory Cell Array]

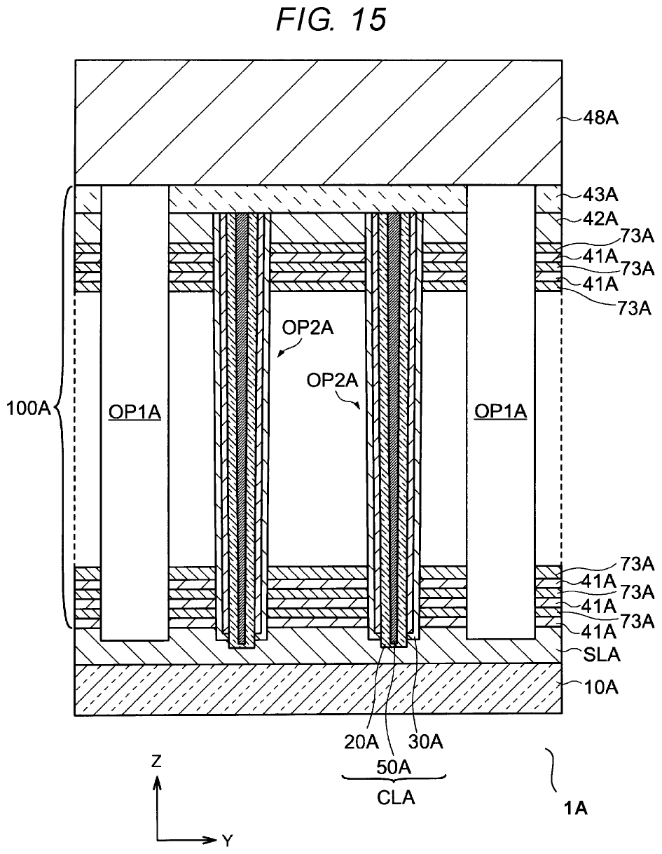

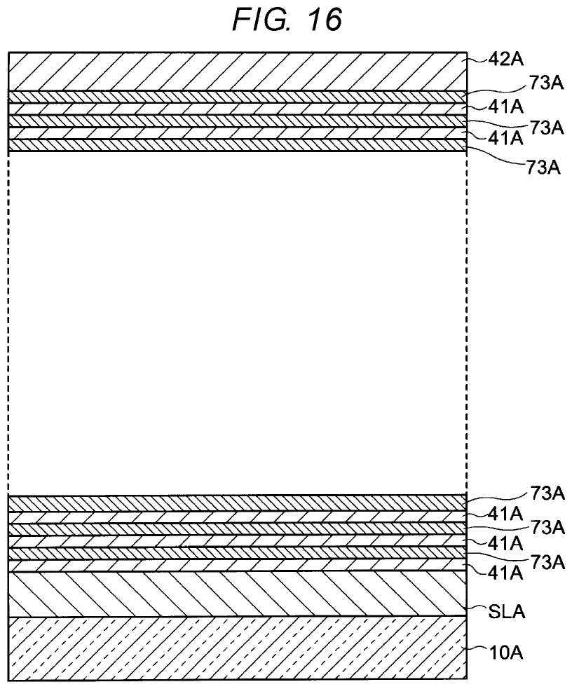

A memory cell array 1A according to a second embodiment and a method for manufacturing the same will be described with reference to FIG. 15 and FIG. 16. While the memory cell array 1A according to the second embodiment is similar to the memory cell array 1 according to the first embodiment, the memory cell array 1A is different from the memory cell array 1 in that an opening OP1A is a gap and a method for manufacturing a stacked body 100A is different. In the following description, the description of the same configuration and manufacturing method as those of the first embodiment will be omitted, and a configuration and a manufacturing method different from those of the first embodiment will be mainly described.

FIG. 15 is a schematic perspective view of the memory cell array 1A according to the second embodiment. The memory cell array 1A includes a substrate 10A. A columnar portion CLA includes a memory layer 30A, a semiconductor layer 20A, and an insulating core layer 50A.

As illustrated in FIG. 15, the opening OP1A of the stacked body 100A is a gap. That is, opening end portions of a conductive layer 73A and an insulating layer 41A near the opening OP1A are exposed to the opening OP1A.

In the same manner as that of the conductive layer 70 of the first embodiment, the conductive layer 73A contains tungsten and an auxiliary material having a smaller amount than that of tungsten and having smaller oxide free energy than that of tungsten. In other words, the conductive layer 73A contains tungsten as a main component, and contains the auxiliary material as an auxiliary component (an additive or an impurity).

As the insulating layer 41A, inorganic insulating layer such as silicon oxide (SiO₂), silicon nitride (SiN), aluminum oxide (Al₂O₃), and aluminum nitride (AlN) may be used. A TEOS layer may be used as the insulating layer 41A.

While FIG. 15 illustrates a configuration in which the opening OP1A is the gap, an insulating layer may be formed in the opening OP1A in the same manner as that of the first embodiment. Alternatively, an insulating layer of a cylindrical shape may be formed in the opening OP1A. When the insulating layer of the cylindrical shape is formed in the opening OP1A, a conductive layer may be formed in a hollow portion of the cylindrical shape.

[Method for Manufacturing Memory Cell Array]

A method for manufacturing the memory cell array 1A according to the second embodiment is similar to that of the memory cell array 1 according to the first embodiment, but a method for manufacturing the stacked body 100A is different from a method for manufacturing the stacked body 100. Specifically, as illustrated in FIG. 16, in the stacked body 100A, the insulating layer 41A is formed on a surface of a source layer SLA, and the conductive layer 73A is formed on the insulating layer 41A. After that, a step of alternately stacking the insulating layer 41A and the conductive layer 73A one layer by one layer is repeated.

The embodiment will describe an example in which a material containing tungsten as a main component and molybdenum as an auxiliary material is used as the conductive layer 73A. However, a material other than molybdenum may be used as the auxiliary material.

The conductive layer 73A is formed by co-sputtering in which a tungsten target is used as a main target and a molybdenum target is used as a sub-target. For example, the conductive layer 73A can be formed by performing sputtering in a state where a pellet of the molybdenum target is disposed on the tungsten target. Alternatively, the conductive layer 73A may be formed by sputtering a mixed target in which molybdenum is introduced into tungsten as a target material.

That is, in the embodiment, the conductive layer 73A can be formed by simultaneously performing film formation of tungsten and the auxiliary material having the smaller oxide free energy than that of tungsten. In other words, the conductive layer 73A contains tungsten as the main component and molybdenum as the auxiliary material in a state immediately after the film formation thereof is performed.

Continuously, the same processes as those of FIG. 5 to FIG. 11 of the first embodiment is performed to form the opening OP1A common to the conductive layer 73A and the insulating layer 41A. Next, an insulating layer 48A is formed on an insulating layer 43A in a state where the opening OP1A is formed, thereby forming the memory cell array 1A illustrated in FIG. 15. An insulating layer 42A is provided on the conductive layer 73A of the uppermost layer, and the insulating layer 43A is provided on the aforementioned insulating layer 42A.

In the embodiment, since a step of performing etching via the opening OP1A is not required, the opening OP1A and the opening OP2A (a memory hole MHA) can be formed in the same step.

As described above, according to the memory cell array 1A of the embodiment, the same effect as that of the memory cell array 1 according to the first embodiment can be obtained. Since the conductive layer 73A containing tungsten and the auxiliary material is formed when the film formation of the stacked body 100A is completed, the memory cell array 1A can be manufactured with a simpler step.

### Modification of Second Embodiment

A modification of the second embodiment will be described with reference to the drawings of the second embodiment. When the modification thereof is described, each member illustrated in FIG. 15 and FIG. 16 used for the description of the second embodiment will be described by replacing an alphabet “A” after the reference sign with an alphabet “B” thereafter.

A conductive layer 73B (refer to FIG. 15 and FIG. 16) in the modification is tungsten similar to that of the conductive layer 70 of the first embodiment. An insulating layer 41B in the modification is an insulating layer mixed with an auxiliary material, which is different from the insulating layer 41A of the second embodiment. The modification will describe a configuration in which a silicon oxide film is used as the insulating layer 41B and molybdenum is used as the auxiliary material mixed in the insulating layer 41B.

In the modification, in a step of FIG. 16, the conductive layer 73B does not contain molybdenum, and the insulating layer 41B contains molybdenum. Next, heating treatment is performed in the state illustrated in FIG. 16. By performing the heating treatment, molybdenum (the auxiliary material) in the insulating layer 41B is diffused into tungsten of the conductive layer 73B. An amount of molybdenum diffused thereinto can be controlled by temperature and time of the heating treatment. In the embodiment, the heating treatment is performed so that a ratio of molybdenum to tungsten in the conductive layer 73B after performing the heating treatment is equal to or greater than 0.001% and equal to or less than 5%. Heating treatment conditions are, for example, equal to or higher than 500° C. and equal to or lower than 1000° C., and equal to or longer than 1 minute and equal to or shorter than 1 hour.

Here, when a material other than molybdenum is used as the auxiliary material, as the auxiliary material, a material that satisfies a condition that the oxide free energy of the auxiliary material is smaller than the oxide free energy of tungsten, and is greater than oxide free energy of an element combined with oxygen in the oxide forming the insulating layer 41B is used. In the modification, since the silicon oxide film is used as the insulating layer 41B, chromium, manganese, niobium, molybdenum, and tantalum may be used as the auxiliary material. When the auxiliary material satisfies the above-described condition, the auxiliary material in the insulating layer 41B can be diffused into tungsten of the conductive layer 73B by performing the heating treatment.

### Third Embodiment

[Cross-Sectional Shape of Stacked Body 100C]

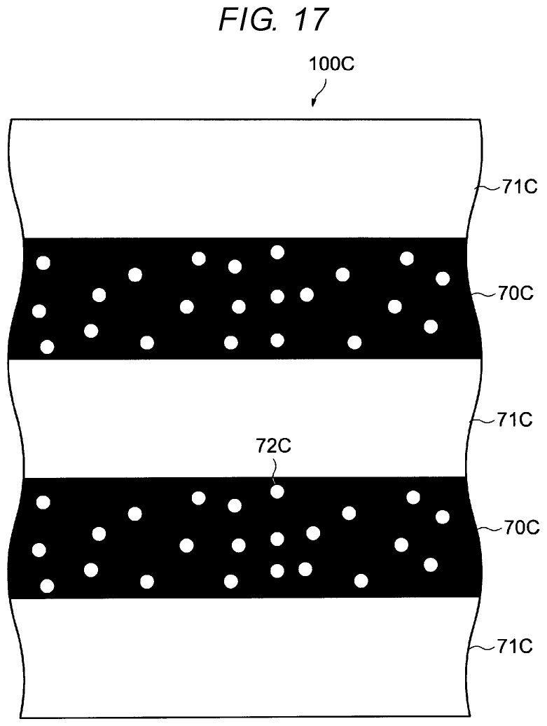

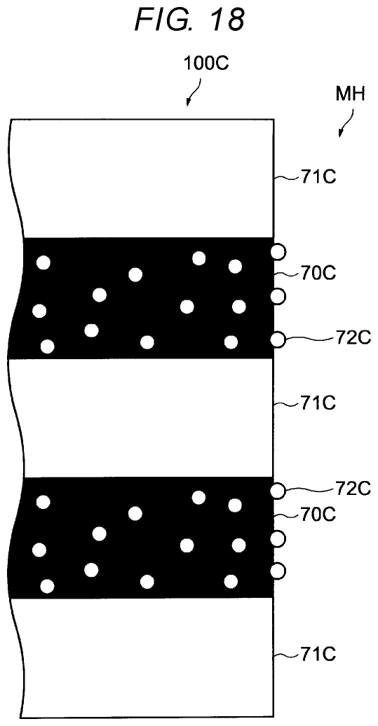

FIG. 17 and FIG. 18 are diagrams illustrating a memory cell array according to a third embodiment. FIG. 17 is a cross-sectional view illustrating the stacked body 100C before the memory hole MH (OP2) illustrated in FIG. 5 is formed. FIG. 18 is a cross-sectional view illustrating a cross-sectional shape of a conductive layer 70C and a conductive layer 71C at an opening end portion of the memory hole MH after the memory hole MH is formed. FIG. 17 and FIG. 18 schematically illustrate a state in which an auxiliary material 72C contained in the conductive layer 71C is diffused into the conductive layer 70C by performing the heating treatment.

In the embodiment, in an etching rate with respect to an etching condition for forming the memory hole MH, an etching rate of the auxiliary material 72C is smaller than an etching rate of the conductive layer 70C. That is, the auxiliary material 72C is less likely to be etched than the conductive layer 70C. When a gas containing chlorine is used as etching for forming the memory hole MH as shown in the embodiment, a melting point of chloride of the auxiliary material 72C is higher than a melting point of chloride of the conductive layer 70C.

As illustrated in FIG. 17, the auxiliary material 72C contained in the conductive layer 71C is diffused inside the conductive layer 70C. When the memory hole MH is formed in the stacked body 100C illustrated in FIG. 17, and, as illustrated in FIG. 18, when a difference between the etching rate of the auxiliary material 72C and the etching rate of the conductive layer 70C is large on the side wall of the conductive layer 70C at the opening end portion of the memory hole MH, the auxiliary material 72C may remain without being etched due to the difference between the respective etching rates. As a result, the auxiliary material 72C may protrude from the side wall of the conductive layer 70C toward the inside of the memory hole MH.

### Modification of Third Embodiment

[Cross-Sectional Shape of Stacked Body 100D]

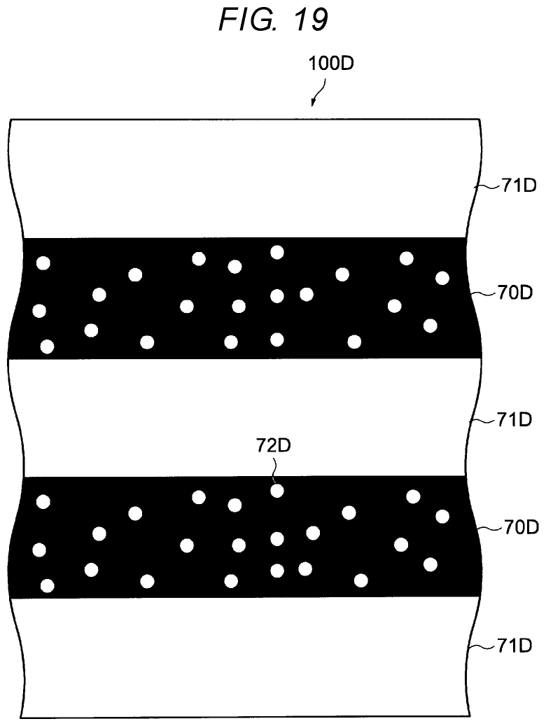

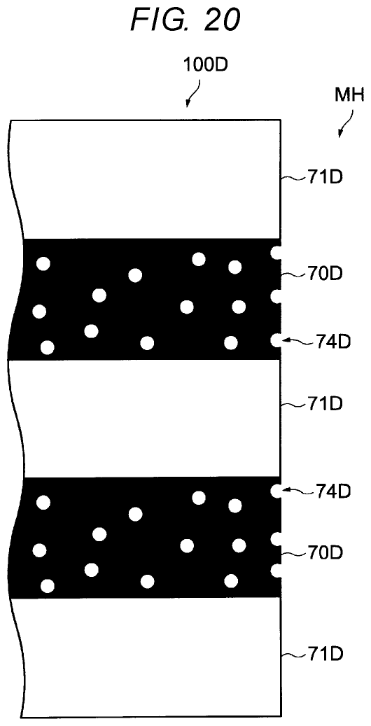

FIG. 19 and FIG. 20 are diagrams illustrating a memory cell array according to a modification of the third embodiment. FIG. 19 is a diagram corresponding to FIG. 17. FIG. 20 is a diagram corresponding to FIG. 18.

In the embodiment, in an etching rate with respect to an etching condition for forming the memory hole MH, an etching rate of an auxiliary material 72D is higher than an etching rate of a conductive layer 70D. That is, the auxiliary material 72D is more easily etched than the conductive layer 70D. When chlorine is used as etching for forming the memory hole MH as shown in the embodiment, a melting point of chloride of the auxiliary material 72D is lower than a melting point of chloride of the conductive layer 70D.

As illustrated in FIG. 19, the auxiliary material 72D contained in a conductive layer 71D is diffused inside the conductive layer 70D. When the memory hole MH is formed in the stacked body 100D illustrated in FIG. 19, and, as illustrated in FIG. 20, when a difference between the etching rate of the auxiliary material 72D and the etching rate of the conductive layer 70D is large on the side wall of the conductive layer 70D at the opening end portion of the memory hole MH, the auxiliary material 72D may be etched first due to the difference between the respective etching rates. As a result, a recessed portion 74D recessed from the side wall of the conductive layer 70D toward the inside of the conductive layer 70D may be formed in a region where the auxiliary material 72D exists.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

Even in the case of another action effect different from an action effect obtained by a mode of each of the above-described embodiments, what is clear from the description of the specification or what can be easily predicted by those skilled in the art is naturally understood as what is obtained by the present disclosure.

What is claimed is:

1. A semiconductor device, comprising:
a stacked body including a plurality of conductive layers insulated from each other;
a semiconductor layer extending into the stacked body; and
a charge storage layer located between one of the conductive layers and the semiconductor layer, wherein
the conductive layer contains tungsten and an auxiliary material, an amount of the auxiliary material being smaller than an amount of tungsten, an oxide free energy of the auxiliary material being smaller than an oxide free energy of tungsten.

2. The semiconductor device according to claim 1, wherein
the auxiliary material contains at least one of molybdenum, niobium, tantalum, or thorium.

3. The semiconductor device according to claim 1, wherein
a combination of tungsten and the auxiliary material is all-proportional solid solution type.

4. The semiconductor device according to claim 3, wherein
the auxiliary material contains at least one of molybdenum, niobium, tantalum, or thorium.

5. The semiconductor device according to claim 1, wherein
a specific resistance of the auxiliary material is equal to or less than three times of a specific resistance of tungsten.

6. The semiconductor device according to claim 5, wherein
the auxiliary material contains at least one of molybdenum, niobium, tantalum, thorium, or gold.

7. The semiconductor device according to claim 1, wherein
a ratio of the auxiliary material to tungsten contained in the conductive layer is equal to or greater than 0.001% and equal to or less than 5%.

8. The semiconductor device according to claim 1, wherein
a concentration of the auxiliary material at an opening end portion near an opening of the conductive layer is higher than a concentration of the auxiliary material inside a pattern of the conductive layer.

9. The semiconductor device according to claim 1, further comprising:
a plurality of memory cells arranged in a direction in which the plurality of conductive layers are stacked, wherein
the plurality of conductive layers are respectively connected to the plurality of memory cells.

10. The semiconductor device according to claim 9, wherein
each of the plurality of memory cells includes a control gate that controls writing or erasing in the memory cell, and
the plurality of conductive layers are respectively connected to the plurality of control gates.

11. A method for manufacturing a semiconductor device that forms a stacked body, the method comprising:
alternately stacking a first conductive layer containing tungsten and a second conductive layer containing an auxiliary material having an oxide free energy smaller than an oxide free energy of tungsten, the first conductive layer and the second conductive layer being in contact with each other;
performing a heating treatment in a state where the first conductive layer and the second conductive layer are stacked;
forming a first opening common to the first conductive layer and the second conductive layer; and
removing the second conductive layer via the first opening.

12. The method for manufacturing the semiconductor device according to claim 11, wherein
the performing the heating treatment includes diffusing, into the first conductive layer, the auxiliary material contained in the second conductive layer.

13. The method for manufacturing the semiconductor device according to claim 11, further comprising:
forming an insulating layer in a region where the second conductive layer is removed.

14. The method for manufacturing the semiconductor device according to claim 11, further comprising:
forming a second opening common to the first conductive layer and the second conductive layer after performing the heating treatment and before forming the first opening, and
forming a charge storage layer and a semiconductor layer in the second opening in a direction in which the first conductive layer and the second conductive layer are stacked.

15. The method for manufacturing the semiconductor device according to claim 14, further comprising:
forming a plurality of memory cells arranged in a direction in which the plurality of conductive layers are stacked, wherein
each of the plurality of memory cells includes a control gate that controls writing or erasing in the memory cell, and
the plurality of conductive layers are respectively connected to the plurality of control gates.

16. A method for manufacturing a semiconductor device that forms a stacked body, the method comprising:
forming a conductive layer by simultaneously performing film formation of tungsten and an auxiliary material having an oxide free energy smaller than an oxide free energy of tungsten, a ratio of the auxiliary material to tungsten being equal to or greater than 0.001% and equal to or less than 5%,
alternately stacking the conductive layer and an insulating layer; and
forming an opening common to the conductive layer and the insulating layer.

17. The method for manufacturing the semiconductor device according to claim 16, further comprising:
forming, in the opening, a plurality of memory cells arranged in a direction in which the conductive layer and the insulating layer are stacked.

18. The method for manufacturing the semiconductor device according to claim 17, wherein
each of the plurality of memory cells includes a control gate that controls writing or erasing in the memory cell, and
the plurality of stacked conductive layers are respectively connected to the plurality of control gates.

19. The method for manufacturing the semiconductor device according to claim 16, wherein the alternately stacking the conductive layer and the insulating layer includes alternately stacking a plurality of conductive layers and insulating layers by:
forming the insulating layer on a surface of a source layer,
forming the conductive layer on the insulating layer, and
repeating a step of alternately forming an insulating layer and a conductive layer.

20. The method for manufacturing the semiconductor device according to claim 16, wherein the conductive layer is not removed via the opening.
